(19) United States
(12) Patent Application Publication
(10) Pub. No.: US 2024/0162217 A1
(43) Pub. Date: May 16, 2024

(54) SEMICONDUCTOR DEVICE AND LAYOUT METHOD OF THE SAME

(71) Applicant: Realtek Semiconductor Corporation, Hsinchu (TW)

(72) Inventors: Tzu-Chieh WEI, Hsinchu (TW); Chun Ying KAN, Hsinchu (TW)

(21) Appl. No.: 18/474,240

(22) Filed: Sep. 26, 2023

(30) Foreign Application Priority Data
Nov. 15, 2022 (TW) 111143584

(51) Int. Cl. H01L 27/02

(52) U.S. Cl. CPC H01L 27/0207

(57) ABSTRACT

A semiconductor device includes a substrate, two first voltage-to-current converters and two second voltage-to-current converters. The substrate includes four layout regions arranged in an array having a plurality of columns and a plurality of rows. The array is line-symmetrical with respect to a first axis and line-symmetrical with respect to a second axis, wherein the first axis perpendicularly intersects the second axis at an array center point of the array. The two first voltage-to-current converters are respectively arranged in two of the four layout regions, wherein layouts of the two first voltage-to-current converters on the substrate are point-symmetrical with respect to the array center point. The two second voltage-to-current converters are respectively arranged in the other two of the four layout regions, wherein layouts of the two second voltage-to-current converters on the substrate are point-symmetrical with respect to the array center point.

### RELATED APPLICATIONS

This application claims priority to Taiwan Application Serial Number 111143584, filed on Nov. 15, 2022, which is herein incorporated by reference in its entirety.

### BACKGROUND

### Technical Field

The disclosure is related to a semiconductor device and a layout method of the same. More particularly, the disclosure is related to a semiconductor device having a voltage-to-current converter with a point-symmetrical structure and a layout method of the same.

### Description of Related Art

Current mirror circuit is a circuit having a function of replicating the current at the input terminal. The current mirror circuit can not only output a current with the same magnitude as the input current, but also output a current that is several times the magnitude of the input current after being adjusted. In addition, because the current mirror circuit has higher output impedance and is able to keep output current stable, the current mirror circuit is often used in semiconductor devices.

Because each transistor of the current mirror circuit has oxide diffusion (OD) regions, in general processes, in order to increase the area utilization ratio of the semiconductor device, all the transistors of the voltage-to-current converter used to generate the same output current in the current mirror circuit are usually aligned in a row and on the same OD region, so that the OD region can be shared between adjacent transistors to reduce the total layout area.

However, due to the gradient effect in efficiency in the process (for example, the angle difference of the light source during manufacturing, the difference of etching, etc.), different voltage-to-current converters on different rows will have different circuit characteristics, resulting in different output capabilities of different voltage-to-current converters, thereby affecting the operation of the semiconductor device. Therefore, how to reduce an output capability variation caused by the layout of the current mirror circuit is one of the subjects in this field.

### SUMMARY

A semiconductor device is provided in present disclosure. The semiconductor device comprises a substrate, two first voltage-to-current converters and two second voltage-to-current converters. The substrate comprises four layout regions arranged as an array having a plurality of columns and a plurality of rows, wherein the array is line-symmetrical with respect to a first axis and line-symmetrical with respect to a second axis, and the first axis perpendicularly intersects the second axis at an array center point of the array. The two first voltage-to-current converters are respectively arranged in two of the four layout regions, wherein layouts of the two first voltage-to-current converters on the substrate are point-symmetrical with respect to the array center point. The two second voltage-to-current converters are respectively arranged in the other two of the four layout regions, wherein layouts of the two second voltage-to-current converters on the substrate are point-symmetrical with respect to the array center point.

A layout method configured for manufacturing a semiconductor device is provided in the present disclosure. The layout method comprises: providing a substrate, wherein the substrate comprises four layout regions arranged as an array having a plurality of columns and a plurality of rows, wherein the array is line-symmetrical with respect to a first axis and line-symmetrical with respect to a second axis, and the first axis perpendicularly intersects the second axis at an array center point of the array; arranging two first voltage-to-current converters in two of the four layout regions, wherein layouts of the two first voltage-to-current converters on the substrate are point-symmetrical with respect to the array center point; and arranging two second voltage-to-current converters in the other two of the four layout regions, wherein layouts of the two second voltage-to-current converters on the substrate are point-symmetrical with respect to the array center point.

With the semiconductor device and the layout method of the same disclosed in the present disclosure, the output capability variation between different current mirror circuits can be improved while maintaining the area utilization rate of the semiconductor device, so as to improve the performance of the semiconductor device.

It should be understood that both the foregoing general description and the following detailed description are by examples, and are intended to provide further explanation of the disclosure as claimed.

### BRIEF DESCRIPTION OF THE DRAWINGS

The present disclosure can be more fully understood by reading the following detailed description of the embodiment, with reference made to the accompanying drawings as follows.

FIG. 1 is a partially schematic diagram of a semiconductor device in accordance with some embodiments of the present disclosure.

FIG. 2A is a schematic diagram of a voltage-to-current converter in accordance with some embodiments of the present disclosure.

FIG. 2B is a schematic diagram of a voltage-to-current converter in accordance with some embodiments of the present disclosure.

FIG. 3 is a layout diagram of a plurality of voltage-to-current converters in accordance with some embodiments of the present disclosure.

FIG. 4 is a diagram of a plurality of sub-converters in accordance with some embodiments of the present disclosure.

FIG. 5 is a layout diagram of a plurality of voltage-to-current converters in accordance with some embodiments of the present disclosure.

FIG. 6 is a partially schematic diagram of a region RG in the semiconductor device of FIG. 5.

### DETAILED DESCRIPTION

Although terms such as “first”, “second”, etc. are used in the present disclosure to describe different elements, these terms are only used to distinguish elements or operations described by the same technical terms. Unless clearly indicated, the terms do not specifically refer to or imply a sequence or an order, nor are they intended to limit the present disclosure.

Reference will now be made in detail to the present embodiments of the disclosure, examples of which are illustrated in the accompanying drawings.

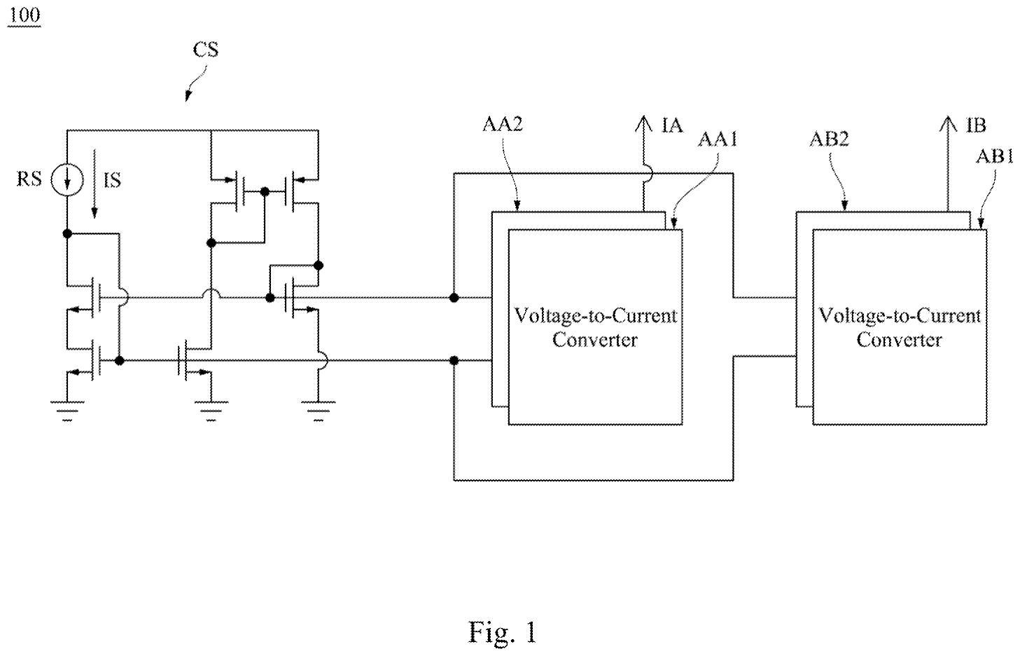

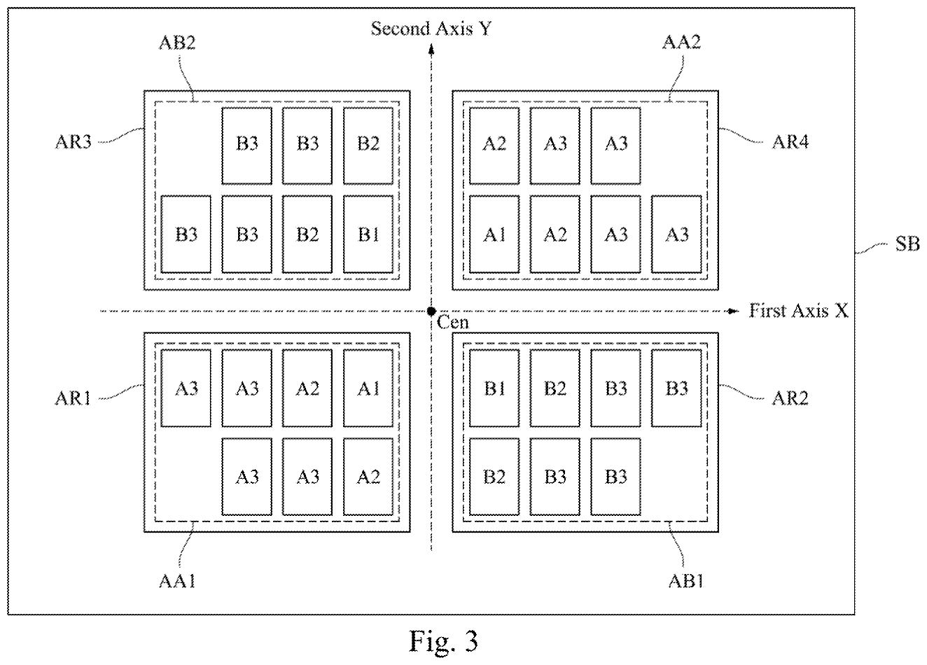

FIG. 1 is a partially schematic diagram of a semiconductor device 100 in accordance with some embodiments of the present disclosure. In some embodiments, the semiconductor device 100 comprises a substrate SB (illustrated in FIG. 3), a current-to-voltage converter CS, first voltage-to-current converters AA1-AA2 and second voltage-to-current converters AB1-AB2. The current-to-voltage converter CS, the first voltage-to-current converters AA1-AA2 and the second voltage-to-current converters AB1-AB2 are arranged on the substrate SB of the semiconductor device 100. The first voltage-to-current converters AA1-AA2 are coupled in parallel and coupled to the current-to-voltage converter CS, and configured to jointly convert an operating voltage provided by the current-to-voltage converter CS into an output current IA. The second voltage-to-current converters AB1-AB2 are coupled in parallel and coupled to the current-to-voltage converter CS, and configured to jointly convert the operating voltage provided by the current-to-voltage converter CS into an output current IB. In some embodiments, the current-to-voltage converter CS and the first voltage-to-current converters AA1-AA2 form a current mirror circuit, and the current-to-voltage converter CS and the second voltage-to-current converters AB1-AB2 form another current mirror circuit.

In some embodiments, the current-to-voltage converter CS comprises a current source RS configured to provide a reference current IS. Operationally, the current-to-voltage converter CS converts the reference current IS into the operating voltage first, then provides the operating voltage to the first voltage-to-current converters AA1-AA2 and the second voltage-to-current converters AB1-AB2. Consequently, the output currents IA and IB output by the first voltage-to-current converters AA1-AA2 and the second voltage-to-current converters AB1-AB2 are related to the reference current IS provided by the current source RS, so as to implement the function of a current mirror.

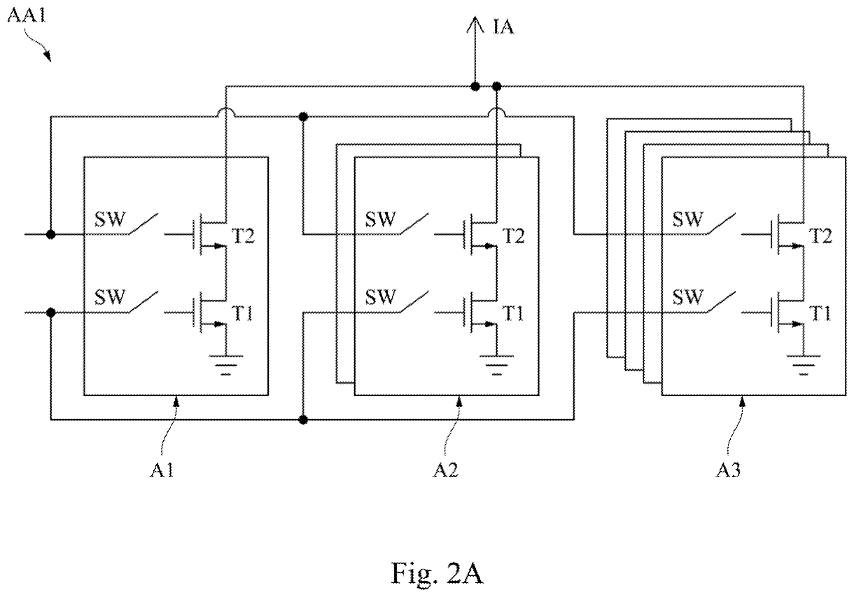

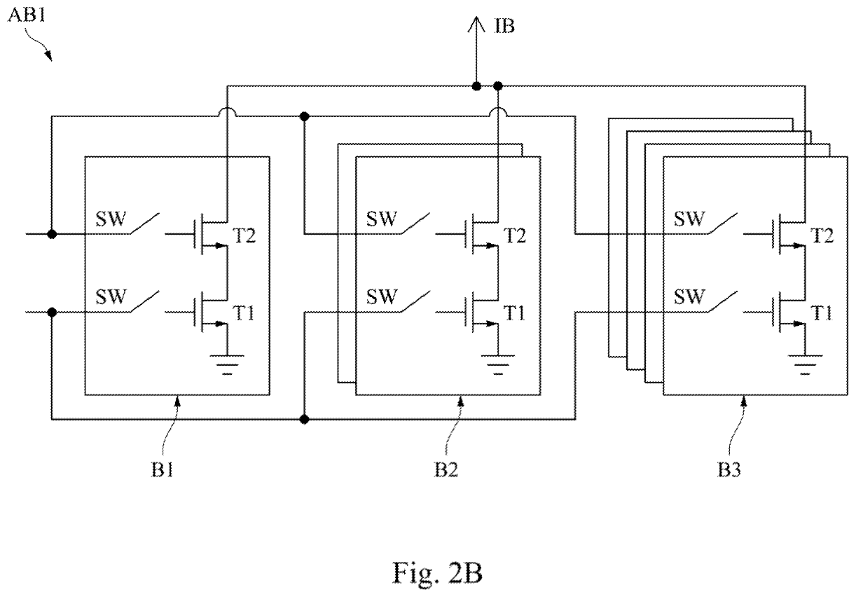

FIG. 2A is a schematic diagram of the first voltage-to-current converter AA1 in accordance with some embodiments of the present disclosure. In some embodiments, the first voltage-to-current converter AA1 comprises one sub-converter A1 coupled in parallel, a plurality of sub-converters A2 coupled in parallel and a plurality of sub-converters A3 coupled in parallel, wherein the number of the sub-converters A2 is twice the number of the sub-converter(s) A1, and the number of the sub-converters A3 is twice the number of the sub-converters A2. Take the embodiments in FIG. 1 and FIG. 2A as an example, the first voltage-to-current converter AA1 comprises one sub-converter A1, two sub-converters A2 and four sub-converters A3. The sub-converters coupled in parallel in the first voltage-to-current converter AA1 (e.g., all of the sub-converter(s) A1 or all of the sub-converters A2) are synchronously enabled. The current generated by the sub-converter(s) A1 is i times the reference current IS, the current generated by the sub-converters A2 is 2i times the reference current IS, and the current generated by the sub-converters A3 is 4i times the reference current IS, wherein i is a positive number. As a result, the first voltage-to-current converter AA1 is able to output the output current IA that is various times the reference current IS.

In some embodiments, each of the sub-converters A1-A3 comprises a first transistor T1, a second transistor T2, and two switches SW respectively coupled to a gate terminal of the first transistor T1 and a gate terminal of the second transistor T2, wherein the first transistor T1 and the second transistor T2 are coupled in series. In response to the sub-converter being enabled, the switches SW of the sub-converter are turned on, so that the gates of the first transistor T1 and the second transistor T2 are electrically coupled to the current-to-voltage converter CS to receive the operating voltage. In response to the sub-converter being disabled, the switches SW of the sub-converter are turned off, so that the gates of the first transistor T1 and the second transistor T2 are insulated from the current-to-voltage converter CS. The first voltage-to-current converters AA1-AA2 comprise similar components, connection relationship and operations. For the sake of brevity, the detailed structure of the first voltage-to-current converter AA2 is not shown in FIG. 2A. It is worth mentioning that the sub-converters corresponding to the same magnification among the first voltage-to-current converters AA1-AA2 coupled in parallel are synchronously enabled or disabled. For example, all sub-converters A1 corresponding to magnification i are synchronously enabled or disabled, and all sub-converters A2 corresponding to magnification 2i are synchronously enabled or disabled.

On the other hand, please refer to FIG. 2B. FIG. 2B is a schematic diagram of the second voltage-to-current converter AB1 in accordance with some embodiments of the present disclosure. The second voltage-to-current converter AB1 comprises one sub-converter B1 coupled in parallel, a plurality of sub-converters B2 coupled in parallel and a plurality of sub-converters B3 coupled in parallel, wherein the number of the sub-converters B2 is twice the number of the sub-converter(s) B1, and the number of the sub-converters B3 is twice the number of the sub-converters B2. Take the embodiments in FIG. 1 and FIG. 2B as an example, the second voltage-to-current converter AB1 comprises one sub-converter B1, two sub-converters B2 and four sub-converters B3. Therefore, the current generated by the sub-converter(s) B1 is i times the reference current IS, the current generated by the sub-converters B2 is 2i times the reference current IS, and the current generated by the sub-converters B3 is 4i times the reference current IS. Each of the sub-converters B1-B3 comprises a first transistor T1 and a second transistor T2 coupled in series. The second voltage-to-current converters AB1-AB2 comprise similar components, connection relationship and operations. For the sake of brevity, the detailed structure of the second voltage-to-current converter AB2 is not shown in FIG. 2B. The second voltage-to-current converters AB1-AB2 operate in the way similar to the first voltage-to-current converters AA1-AA2. For the sake of brevity, detailed description is omitted.

In order to clearly illustrate the layouts of the first voltage-to-current converters AA1-AA2 and the second voltage-to-current converters AB1-AB2 in the semiconductor device 100, please also refer to FIG. 3. FIG. 3 is a layout diagram of the first voltage-to-current converters AA1-AA2 and the second voltage-to-current converters AB1-AB2 in accordance with some embodiments of the present disclosure.

In some embodiments, the substrate SB of the semiconductor device 100 comprises layout regions AR1-AR4. The layout regions AR1-AR4 are arranged in the semiconductor device 100 as an array in which each column and each row includes two layout regions. The array is line-symmetrical with respect to a first axis X which is parallel to the substrate SB, and is line-symmetrical with respect to a second axis Y which is parallel to the substrate SB, wherein the first axis X perpendicularly intersects the second axis Y at an array center point Cen.

The first voltage-to-current converters AA1 and AA2 are respectively arranged in the layout regions AR1 and AR4, and the two second voltage-to-current converters AB1 and AB2 are respectively arranged in the layout regions AR2 and AR3. The layouts of the first voltage-to-current converters AA1-AA2 on the substrate SB are point-symmetrical with respect to the array center point Cen, and the layouts of the second voltage-to-current converters AB1-AB2 on the substrate SB are also point-symmetrical with respect to the array center point Cen.

As shown in FIG. 3, the sub-converters of the first voltage-to-current converters AA1-AA2 synchronously enabled are point-symmetrical with respect to the array center point Cen. For example, the sub-converters A1 of the first voltage-to-current converters AA1-AA2 are point-symmetrical with respect to the array center point Cen. For another example, the sub-converters A2 of the first voltage-to-current converters AA1-AA2 are also point-symmetrical with respect to the array center point Cen. The sub-converters of the second voltage-to-current converters AB1-AB2 synchronously enabled are also point-symmetrical with respect to the array center point Cen. For example, the sub-converters B1 of the second voltage-to-current converters AB1-AB2 are point-symmetrical with respect to the array center point Cen.

In other words, according to the quantitative relationship of the aforementioned sub-converters A1-A3, in the first voltage-to-current converters AA1-AA2, N sub-converters (i.e., the sub-converters A1) are synchronously enabled and point-symmetrical with respect to the array center point Cen, another 2N sub-converters (i.e., the sub-converters A2) are synchronously enabled and point-symmetrical with respect to the array center point Cen, and yet another 4N sub-converters (i.e., the sub-converters A3) are synchronously enabled and point-symmetrical with respect to the array center point Cen, wherein N is a positive integer.

Similarly, according to the quantitative relationship of the aforementioned sub-converters B1-B3, in the second voltage-to-current converters AB1-AB2, N sub-converters (i.e., the sub-converters B1) are synchronously enabled and point-symmetrical with respect to the array center point Cen, another 2N sub-converters (i.e., the sub-converters B2) are synchronously enabled and point-symmetrical with respect to the array center point Cen, and yet another 4N sub-converters (i.e., the sub-converters B3) are synchronously enabled and point-symmetrical with respect to the array center point Cen.

With the above-mentioned point-symmetrical layout method, in the semiconductor device 100, not only the strengths of the gradient effect in efficiency to the voltage-to-current converters coupled in parallel (e.g., the first voltage-to-current converters AA1 and AA2) in the process are almost the same, but also the strengths of the gradient effect in efficiency to the voltage-to-current converters not coupled in parallel (e.g., the first voltage-to-current converters AA1-AA2 and the second voltage-to-current converters AB1-AB2) in the process are almost the same. In other words, the gradient effects in efficiency to all voltage-to-current converters in the semiconductor device 100 are almost the same, thus the output capability variation can be improved, so that the output currents IA and IB can be the same (the same magnification of the reference current IS). The details are described in following paragraphs.

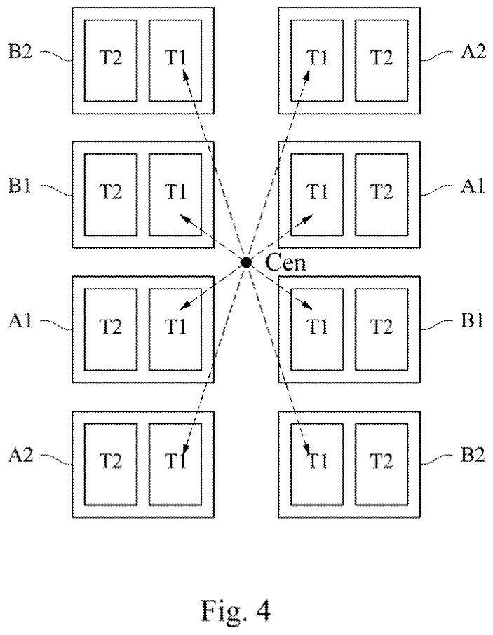

FIG. 4 is a diagram of the sub-converters A1, A2, B1 and B2 in accordance with some embodiments of the present disclosure. For two sub-converters A1 point-symmetrical with respect to the array center point Cen, their respective first transistors T1 are also point-symmetrical to each other, and their respective second transistors T2 are also point-symmetrical to each other. Additionally, for two sub-converters B1 point-symmetrical with respect to the array center point Cen, their respective first transistors T1 are also point-symmetrical to each other, and their respective second transistors T2 are also point-symmetrical to each other. In conclusion, for the ones of sub-converters A1, A2, B1 and B2 that are synchronously enabled, they are not only arranged in positions of the layout that are point-symmetrical with respect to the array center point Cen, but also comprising transistors with circuit structures that are point-symmetrical with respect to the array center point Cen.

In FIG. 4, the length of the dotted arrow indicates the strength of the gradient effect in efficiency during the process in various positions of the layout. As shown in FIG. 4, in all voltage-to-current converters, sub-converters corresponding to the same magnification receive similar strength of the gradient effects in efficiency, thus have similar characteristic variations. For example, the two sub-converters A1 in the first voltage-to-current converters AA1-AA2 corresponding to magnification i and the two sub-converters B1 in the second voltage-to-current converters AB1-AB2 corresponding to magnification i receive similar strength of the gradient effect in efficiency.

In conclusion, since the total strength of the gradient effect in efficiency received by the first voltage-to-current converters AA1-AA2 is similar to the total strength of the gradient effect in efficiency received by the second voltage-to-current converters AB1-AB2, the output current IA is similar to the output current IB.

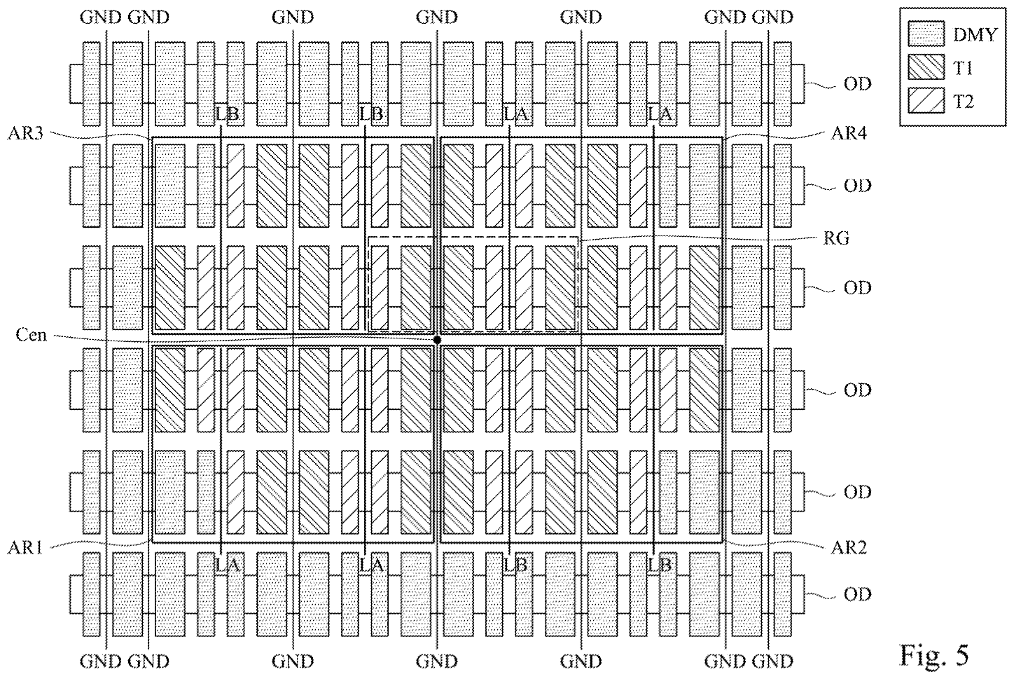

FIG. 5 is a layout diagram of the semiconductor device 100 in accordance with some embodiments of the present disclosure. Please refer to FIG. 3 and FIG. 5 together. In some embodiments, the semiconductor device 100 further comprises a plurality of oxide diffusion regions OD arranged on the substrate SB in parallel to the first axis X. Two of the oxide diffusion regions OD overlay with the layout regions AR1 and AR2, and another two of the oxide diffusion regions OD overlay with the layout regions AR3 and AR4. A part of the plurality of the first transistors T1 and a part of the plurality of the second transistors T2 are alternately arranged on the same oxide diffusion region OD, so as to form a part of the sub-converters A1-A3 and a part of the sub-converters B1-B3.

In some embodiments, the semiconductor device 100 further comprises a plurality of dummy transistors DMY. The plurality of dummy transistors DMY are arranged on the oxide diffusion regions OD and around the layout regions AR1-AR4, and configured to reduce the leakage current of the first voltage-to-current converters AA1-AA2 and the second voltage-to-current converters AB1-AB2.

Please refer to FIGS. 2A-2B and FIG. 5 together again. In some embodiments, in a situation that the first transistors T1 and the second transistors T2 of the semiconductor device 100 are N-type transistors, source terminals S of the first transistors T1 are coupled to a ground line GND, drain terminals D of the second transistors T2 of the first voltage-to-current converters AA1-AA2 are coupled to a current line LA for transmitting the output current IA, and drain terminals D of the second transistors T2 of the second voltage-to-current converters AB1-AB2 are coupled to a current line LB for transmitting the output current IB.

In other embodiments not shown, in a situation that the first transistors T1 and the second transistors T2 of the semiconductor device 100 are P-type transistors, the source terminals S of the first transistors T1 are coupled to a power line for receiving the reference voltage, the drain terminals D of the second transistors T2 of the first voltage-to-current converters AA1-AA2 are coupled to the current line LA for transmitting the output current IA, and the drain terminals D of the second transistors T2 of the second voltage-to-current converters AB1-AB2 are coupled to the current line LB for transmitting the output current IB.

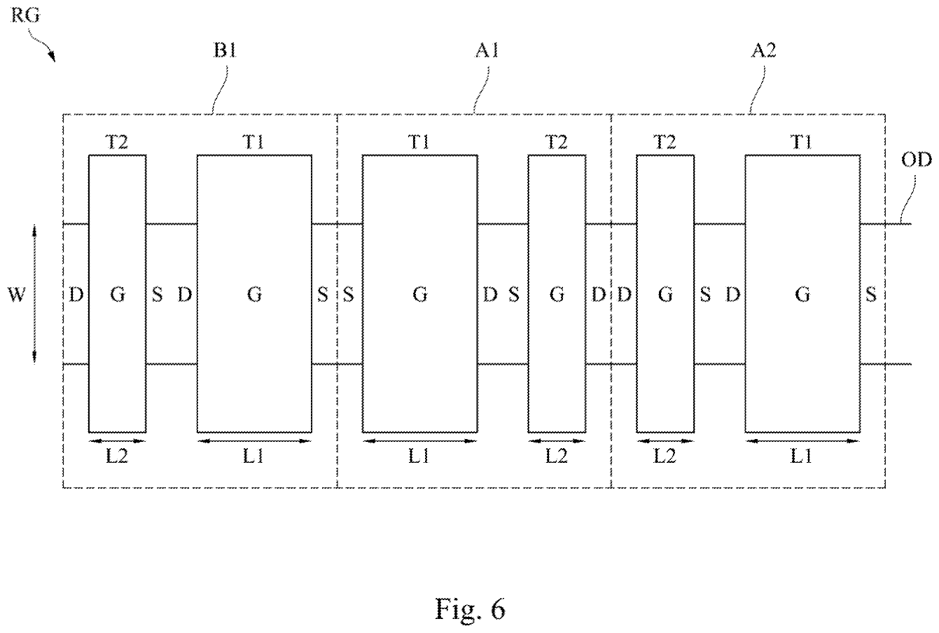

FIG. 6 is a partially schematic diagram of a region RG in the semiconductor device 100 of FIG. 5. According to the way of connection, the oxide diffusion region OD can act as the drain terminal D or the source terminal S of the transistor. In some embodiments, in a situation that a first transistor T1 is coupled to a second transistor T2 in the same oxide diffusion region OD, the drain terminal D of the first transistor T1 is coupled to the source terminal S of the second transistor T2.

Take the embodiments of FIG. 6 as an example, in the region RG, the first transistors T1 and the second transistors T2 of the sub-converters B1, A1 and A2 are arranged on the same oxide diffusion region OD. As shown in FIG. 6, since the first transistor T1 of the sub-converter B1 is adjacent to the second transistor T2 of the sub-converter B1, the drain terminal D of the first transistor T1 of the sub-converter B1 is coupled to the source terminal S of the second transistor T2 of the sub-converter B1. Since the first transistor T1 of the sub-converter A1 is adjacent to the second transistor T2 of the sub-converter A1, the drain terminal D of the first transistor T1 of the sub-converter A1 is coupled to the source terminal S of the second transistor T2 of the sub-converter A1. Since the first transistor T1 of the sub-converter A2 is adjacent to the second transistor T2 of the sub-converter A2, the drain terminal D of the first transistor T1 of the sub-converter A2 is coupled to the source terminal S of the second transistor T2 of the sub-converter A2.

On the other hand, in a situation that a first transistor T1 is coupled to another first transistor T1 in the same oxide diffusion region OD, the source terminals S of the two first transistors T1 are coupled to each other. Please refer to FIG. 6 again. Since the first transistor T1 of the sub-converter A1 is adjacent to the first transistor T1 of the sub-converter B1, the source terminals S of the first transistors T1 of the sub-converters A1 and B1 are coupled to each other and coupled to the ground line GND (not shown).

Moreover, in a situation that a second transistor T2 is coupled to another second transistor T2 in the same oxide diffusion region OD, the drain terminals D of the two second transistors T2 are coupled to each other. Please refer to FIG. 6 again. Since the second transistor T2 of the sub-converter A1 is adjacent to the second transistor T2 of the sub-converter A2, the drain terminals D of the second transistors T2 of the sub-converters A1 and A2 are coupled to each other.

In some embodiments, the gate terminals G of the first transistors T1 have gate lengths L1, the gate terminals G of the second transistors T2 have gate lengths L2, wherein the gate lengths L1 are greater than or equal to the gate lengths L2.

In some embodiments, the gate terminals G of the first transistors T1 and the second transistors T2 have the same effective gate widths W.

Please refer to FIG. 5 again. In some embodiments, in a situation that a dummy transistor DMY is coupled to a first transistor T1 in the same oxide diffusion region OD, the source terminal of the dummy transistor DMY is coupled to the source terminal S of the first transistors T1, and the gate terminal of the dummy transistor has the same gate length L1 and gate width W that the gate terminal G of the first transistor T1 has. On the other hand, in a situation that a dummy transistor DMY is coupled to a second transistor T2 in the same oxide diffusion region OD, the drain terminal of the dummy transistor DMY is coupled to the drain terminal D of the second transistors T2, and the gate terminal of the dummy transistor has the same gate length L2 and gate width W that the gate terminal G of the second transistor T2 has.

A layout method configured for manufacturing the semiconductor device 100 is provided in the present disclosure. The layout method comprises: providing the substrate SB; arranging the first voltage-to-current converters AA1 and AA2 in two of the layout regions AR1-AR4; and arranging the second voltage-to-current converters AB1 and AB2 in the other two of the layout regions AR1-AR4. Wherein the layout regions AR1-AR4 are arranged as an array having a plurality of columns and a plurality of rows, wherein the array is line-symmetrical with respect to the first axis X and line-symmetrical with respect to the second axis Y, and the first axis X perpendicularly intersects the second axis Y at the array center point Cen of the array. The layouts of the first voltage-to-current converters AA1 and AA2 on the substrate SB are point-symmetrical with respect to the array center point Cen. The layouts of the second voltage-to-current converters AB1 and AB2 on the substrate SB are point-symmetrical with respect to the array center point Cen.

With the semiconductor device 100 and the layout method of the same provided in the present disclosure, the problem of the output capability variation caused by the gradient effect in efficiency can be reduced while the area of the oxide diffusion regions OD are utilized effectively, so as to improve the reliability of the semiconductor device 100.

The above are preferred embodiments of the present disclosure. It will be apparent to those skilled in the art that various modifications and variations can be made to the structure of the present disclosure without departing from the scope or spirit of the present disclosure. In view of the foregoing, it is intended that the present disclosure cover modifications and variations of this disclosure provided they fall within the scope of the following claims and their equivalents.

What is claimed is:

1. A semiconductor device, comprising:
a substrate, comprising four layout regions, wherein the four layout regions are arranged as an array having a plurality of columns and a plurality of rows, wherein the array is line-symmetrical with respect to a first axis and line-symmetrical with respect to a second axis, and the first axis perpendicularly intersects the second axis at an array center point of the array;
two first voltage-to-current converters, respectively arranged in two of the four layout regions, wherein layouts of the two first voltage-to-current converters on the substrate are point-symmetrical with respect to the array center point; and
two second voltage-to-current converters, respectively arranged in the other two of the four layout regions, wherein layouts of the two second voltage-to-current converters on the substrate are point-symmetrical with respect to the array center point.

2. The semiconductor device of claim 1, wherein
the two first voltage-to-current converters comprise a plurality of first sub-converters, the two second voltage-to-current converters comprise a plurality of second sub-converters;
layouts of plurality of first sub-converters of one of the two first voltage-to-current converters are point-symmetrical to layouts of plurality of first sub-converters of the other one of the two first voltage-to-current converters, with respect to the array center point; and
layouts of plurality of second sub-converters of one of the two second voltage-to-current converters are point-symmetrical to layouts of plurality of second sub-converters of the other one of the two second voltage-to-current converters, with respect to the array center point.

3. The semiconductor device of claim 2, wherein ones of the plurality of first sub-converters synchronously enabled are point-symmetrical with respect to the array center point, and ones of the plurality of second sub-converters synchronously enabled are point-symmetrical with respect to the array center point.

4. The semiconductor device of claim 2, wherein
each of the plurality of first sub-converters and each of the plurality of second sub-converters comprise a first transistor and a second transistor;
the plurality of first transistors of the plurality of first sub-converters and the plurality of second sub-converters have first gate lengths that are the same;
the plurality of second transistors of the plurality of first sub-converters and the plurality of second sub-converters have second gate lengths that are the same, wherein the first gate lengths are greater than or equal to the second gate lengths; and
the plurality of first transistors and the plurality of second transistors have effective gate widths that are the same.

5. The semiconductor device of claim 4, further comprising:
a plurality of oxide diffusion regions, arranged on the substrate in parallel to the first axis, wherein two of the plurality of oxide diffusion regions overlay with two of the four layout regions, another two of the plurality of oxide diffusion regions overlay with the other two of the four layout regions,
wherein a part of the plurality of the first transistors and a part of the plurality of the second transistors are alternately arranged on the same oxide diffusion region, so as to form a part of the plurality of first sub-converters and a part of the plurality of second sub-converters.

6. The semiconductor device of claim 5, wherein each of the plurality of first transistors and each of the plurality of second transistors comprise a source terminal and a drain terminal;
the drain terminal of each of the plurality of first transistors is coupled to the source terminal of an adjacent one of the plurality of second transistors, and is arranged on the same oxide diffusion region with the adjacent one of the plurality of second transistors;
the source terminal of each of the plurality of first transistors is coupled to the source terminal of an adjacent one of the plurality of first transistors, and is arranged on the same oxide diffusion region with the adjacent one of the plurality of first transistor; and
the drain terminals of two of the plurality of second transistors, that are adjacent to each other and arranged on the same oxide diffusion region, are coupled to each other.

7. The semiconductor device of claim 6, further comprising:
a plurality of dummy transistors, arranged on the substrate and around the four layout regions, the plurality of dummy transistors each comprises a source terminal and a drain terminal,
wherein in a situation that one of the plurality of dummy transistors is adjacent to one of the plurality of first transistors in the same oxide diffusion region, the source terminal of the one of the plurality of dummy transistors is coupled to the source terminal of the one of the plurality of first transistors, and
wherein in a situation that the one of the plurality of dummy transistors is adjacent to one of the plurality of second transistors in the same oxide diffusion region, the drain terminal of the one of the plurality of dummy transistors is coupled to the drain terminal of the one of the plurality of second transistors.

8. The semiconductor device of claim 7, wherein in the situation that the one of the plurality of dummy transistors is adjacent to the one of the plurality of first transistors in the same oxide diffusion region, both the one of the plurality of dummy transistors and the one of the plurality of first transistors have the same effective gate widths and the same first gate lengths; and
in the situation that the one of the plurality of dummy transistors is adjacent to the one of the plurality of second transistors in the same oxide diffusion region, both the one of the plurality of dummy transistors and the one of the plurality of second transistors have the same effective gate widths and the same second gate lengths.

9. The semiconductor device of claim 6, wherein in a situation that the plurality of first transistors and the plurality of second transistors are N-type transistors, the source terminals of the plurality of first transistors are coupled to a ground line, the drain terminals of the plurality of second transistors of the plurality of first voltage-to-current converters are coupled to one of a plurality of current lines, the drain terminals of the plurality of second transistors of the plurality of second voltage-to-current converters are coupled to another one of the plurality of current lines; and
in a situation that the plurality of first transistors and the plurality of second transistors are P-type transistors, the source terminals of the plurality of first transistors are coupled to a power line, the drain terminals of the plurality of second transistors of the plurality of first voltage-to-current converters are coupled to the one of a plurality of current lines, the drain terminals of the plurality of second transistors of the plurality of second voltage-to-current converters are coupled to the another one of the plurality of current lines.

10. The semiconductor device of claim 2, wherein N of the plurality of first sub-converters are synchronously enabled and point-symmetrical with respect to the array center point,
another 2N of the plurality of first sub-converters are synchronously enabled and point-symmetrical with respect to the array center point,
yet another 4N of the plurality of first sub-converters are synchronously enabled and point-symmetrical with respect to the array center point,
N of the plurality of second sub-converters are synchronously enabled and point-symmetrical with respect to the array center point,
another 2N of the plurality of second sub-converters are synchronously enabled and point-symmetrical with respect to the array center point, and
yet another 4N of the plurality of second sub-converters are synchronously enabled and point-symmetrical with respect to the array center point, wherein N is a positive integer.

11. A layout method for manufacturing a semiconductor device, comprising:
providing a substrate, wherein the substrate comprises four layout regions arranged as an array having a plurality of columns and a plurality of rows, wherein the array is line-symmetrical with respect to a first axis and line-symmetrical with respect to a second axis, and the first axis perpendicularly intersects the second axis at an array center point of the array;
arranging two first voltage-to-current converters in two of the four layout regions, wherein layouts of the two first voltage-to-current converters on the substrate are point-symmetrical with respect to the array center point; and
arranging two second voltage-to-current converters in the other two of the four layout regions, wherein layouts of the two second voltage-to-current converters on the substrate are point-symmetrical with respect to the array center point.

12. The layout method of claim 11, wherein
the two first voltage-to-current converters comprise a plurality of first sub-converters, the two second voltage-to-current converters comprise a plurality of second sub-converters;
layouts of plurality of first sub-converters of one of the two first voltage-to-current converters are point-symmetrical to layouts of plurality of first sub-converters of the other one of the two first voltage-to-current converters, with respect to the array center point; and
layouts of plurality of second sub-converters of one of the two second voltage-to-current converters are point-symmetrical to layouts of plurality of second sub-converters of the other one of the two second voltage-to-current converters, with respect to the array center point.

13. The layout method of claim 12, wherein ones of the plurality of first sub-converters synchronously enabled are point-symmetrical with respect to the array center point, and ones of the plurality of second sub-converters synchronously enabled are point-symmetrical with respect to the array center point.

14. The layout method of claim 12, wherein
each of the plurality of first sub-converters and each of the plurality of second sub-converters comprise a first transistor and a second transistor;
the plurality of first transistors of the plurality of first sub-converters and the plurality of second sub-converters have first gate lengths that are the same;
the plurality of second transistors of the plurality of first sub-converters and the plurality of second sub-converters have second gate lengths that are the same, wherein the first gate lengths are greater than or equal to the second gate lengths; and
the plurality of first transistors and the plurality of second transistors have effective gate widths that are the same.

15. The layout method of claim 14, further comprising:
arranging a plurality of oxide diffusion regions on the substrate in parallel to the first axis, wherein two of the plurality of oxide diffusion regions overlay with two of the four layout regions, another two of the plurality of oxide diffusion regions overlay with the other two of the four layout regions,
wherein a part of the plurality of the first transistors and a part of the plurality of the second transistors are alternately arranged on the same oxide diffusion region, so as to form a part of the plurality of first sub-converters and a part of the plurality of second sub-converters.

16. The layout method of claim 15, wherein
each the plurality of first transistors and each of the plurality of second transistors comprise a source terminal and a drain terminal;
the drain terminal of each of the plurality of first transistors is coupled to the source terminal of an adjacent one of the plurality of second transistors, and is arranged on the same oxide diffusion region with the adjacent one of the plurality of second transistors;
the source terminal of each of the plurality of first transistors is coupled to the source terminal of an adjacent one of the plurality of first transistors, and is arranged on the same oxide diffusion region with the adjacent one of the plurality of first transistors; and
the drain terminals of two of the plurality of second transistors, that are adjacent to each other and arranged on the same oxide diffusion region, are coupled to each other.

17. The layout method of claim 16, further comprising:
arranging a plurality of dummy transistors on the substrate, the plurality of dummy transistors are around the four layout regions and each comprises a source terminal and a drain terminal,
wherein in a situation that one of the plurality of dummy transistors is adjacent to one of the plurality of first transistors in the same oxide diffusion region, the source terminal of the one of the plurality of dummy transistors is coupled to the source terminal of the one of the plurality of first transistors; and
wherein in a situation that the one of the plurality of dummy transistors is adjacent to one of the plurality of second transistors in the same oxide diffusion region, the drain terminal of the one of the plurality of dummy transistors is coupled to the drain terminal of the one of the plurality of second transistors.

18. The layout method of claim 17, wherein
in the situation that the one of the plurality of dummy transistors is adjacent to the one of the plurality of first transistors in the same oxide diffusion region, both the one of the plurality of dummy transistors and the one of the plurality of first transistors have the same effective gate widths and the same first gate lengths; and
in the situation that the one of the plurality of dummy transistors is adjacent to the one of the plurality of second transistors in the same oxide diffusion region, both the one of the plurality of dummy transistors and the one of the plurality of second transistors have the same effective gate widths and the same second gate lengths.

19. The layout method of claim 16, wherein
in a situation that the plurality of first transistors and the plurality of second transistors are N-type transistors, the source terminals of the plurality of first transistors are coupled to a ground line, the drain terminals of the plurality of second transistors of the plurality of first voltage-to-current converters are coupled to one of a plurality of current lines, the drain terminals of the plurality of second transistors of the plurality of second voltage-to-current converters are coupled to another one of the plurality of current lines; and
in a situation that the plurality of first transistors and the plurality of second transistors are P-type transistors, the source terminals of the plurality of first transistors are coupled to a power line, the drain terminals of the plurality of second transistors of the plurality of first voltage-to-current converters are coupled to the one of a plurality of current lines, the drain terminals of the plurality of second transistors of the plurality of second voltage-to-current converters are coupled to the another one of the plurality of current lines.

20. The layout method of claim 12, wherein
N of the plurality of first sub-converters are synchronously enabled and point-symmetrical with respect to the array center point,
another 2N of the plurality of first sub-converters are synchronously enabled and point-symmetrical with respect to the array center point,
yet another 4N of the plurality of first sub-converters are synchronously enabled and point-symmetrical with respect to the array center point,
N of the plurality of second sub-converters are synchronously enabled and point-symmetrical with respect to the array center point,
another 2N of the plurality of second sub-converters are synchronously enabled and point-symmetrical with respect to the array center point, and
yet another 4N of the plurality of second sub-converters are synchronously enabled and point-symmetrical with respect to the array center point, wherein N is a positive integer.
